(19) United States
(12) Patent Application Publication
(10) Pub. No.: US 2024/0414951 A1
(43) Pub. Date: Dec. 12, 2024

(54) DISPLAY DEVICE AND METHOD OF MANUFACTURING THE SAME

(71) Applicant: Samsung Display Co., LTD., Yongin-si (KR)

(72) Inventors: Sung Hune YOO, Yongin-si (KR); Dong Wook LEE, Yongin-si (KR)

(73) Assignee: Samsung Display Co., LTD., Yongin-si (KR)

(21) Appl. No.: 18/628,198

(22) Filed: Apr. 5, 2024

(30) Foreign Application Priority Data
Jun. 9, 2023 (KR) 10-2023-0074268

(51) Int. Cl. H10K 59/122; H10K 59/12; H10K 71/60

(52) U.S. Cl. CPC H10K 59/122; H10K 59/1201; H10K 71/60

(57) ABSTRACT

A display device includes a base substrate, a first pixel electrode disposed on the base substrate, a pixel defining layer disposed on the first pixel electrode and including an opening exposing the first pixel electrode, an organic light emitting unit disposed on the first pixel electrode, and a second pixel electrode disposed on the organic light emitting unit. The organic light emitting unit includes a first functional layer disposed on the first pixel electrode and including a lower surface contacting the first pixel electrode and an upper surface opposite to the lower surface, a light emitting layer disposed on the first functional layer, and a third functional layer disposed on the light emitting layer and including a lower surface contacting the light emitting layer and an upper surface opposite to the lower surface.

### CROSS REFERENCE TO RELATED APPLICATION(S)

This application claims priority to and benefits of Korean Patent Application No. 10-2023-0074268 under 35 U.S.C. § 119, filed on Jun. 9, 2023, in the Korean Intellectual Property Office, the entire content of which are incorporated herein by reference.

### BACKGROUND

### 1. Technical Field

Embodiments relate to a display device and a method of manufacturing the display device.

### 2. Description of the Related Art

As information society develops, a demand for a display device for displaying an image has increased in various forms. For example, the display device is applied to various electronic devices such as a smart phone, a digital camera, a notebook computer, a navigation device, and a smart television.

The display device includes a flat panel display device such as a liquid crystal display device, a field emission display device, or a light emitting display device. The light emitting display device includes an organic light emitting display device including an organic light emitting element, an inorganic light emitting display device including an inorganic light emitting element such as an inorganic semiconductor, and an ultra-small light emitting display device including an ultra-small light emitting element.

The organic light emitting display device includes an organic light emitting element including a hole injection electrode, an electron injection electrode, and an organic light emitting layer formed therebetween, and a self-emissive display device in which light is generated as an exciton generated by combination of a hole injected from the hole injection electrode and an electron injected from the electron injection electrode in the organic light emitting layer falls from an excited state to a ground state. Since such an organic light emitting display device has a fast response speed and is driven with low power consumption, the organic light emitting display device is attracting attention as a next-generation display.

### SUMMARY

Embodiments provide a display device providing a shape for each of light generation layers forming an organic light emitting unit, which are capable of widening an area in which a thickness of the light generation layers is uniformly maintained.

Embodiments provide a display device capable of improving light emission efficiency by widening an area in which the thickness of the light generation layers forming the organic light emitting unit is uniformly maintained.

Embodiments provide a display device providing a shape for each of the light generation layers forming the organic light emitting unit, which are for widening an area in which the thickness of the light generation layers is uniformly maintained.

Embodiments provide a method of manufacturing the display device.

However, embodiments are not limited to those set forth herein. The above and other embodiments will become more apparent to one of ordinary skill in the art to which the disclosure pertains by referencing the detailed description of the disclosure given below.

In accordance with an aspect of the invention, a display device may include a base substrate, a first pixel electrode disposed on the base substrate, a pixel defining layer disposed on the first pixel electrode and including an opening exposing the first pixel electrode, an organic light emitting unit disposed on the first pixel electrode, and a second pixel electrode disposed on the organic light emitting unit. The organic light emitting unit may include a first functional layer disposed on the first pixel electrode and including a lower surface contacting the first pixel electrode and an upper surface opposite to the lower surface, a light emitting layer disposed on the first functional layer, and a third functional layer disposed on the light emitting layer and including a lower surface contacting the light emitting layer and an upper surface opposite to the lower surface, the upper surface of the first functional layer may include first concave portions and a first convex portion formed between the first concave portions, and the upper surface of the third functional layer may include a flat surface overlapping the first convex portion of the first functional layer in a plan view.

According to an embodiment, the upper surface of the third functional layer may include inclined surfaces, and the flat surface of the third functional layer may be disposed between the inclined surfaces of the third functional layer.

According to an embodiment, the display device may further include a second functional layer disposed between the first functional layer and the light emitting layer and including a lower surface contacting the first functional layer and an upper surface contacting the organic light emitting unit, and the upper surface of the second functional layer may include second concave portions and a second convex portion formed between the second concave portions.

According to an embodiment, a difference between a minimum height of the second concave portions and a maximum height of the second convex portion may be less than a difference between a minimum height of the first concave portions and a maximum height of the first convex portion.

According to an embodiment, a difference between a height of a lowest point of the second concave portions and a height of a highest point of the second convex portion may be equal to or less than about 10 nm.

According to an embodiment, the light emitting layer may include a lower surface contacting the upper surface of the second functional layer and an upper surface contacting the lower surface of the third functional layer, the lower surface of the second functional layer may have a surface profile of the upper surface of the first functional layer, and the lower surface of the light emitting layer may have a surface profile of the upper surface of the second functional layer.

According to an embodiment, the second convex portion may overlap the first convex portion in a plan view.

According to an embodiment, the upper surface of the first functional layer may include at least one first inflection point, the upper surface of the second functional layer may include at least one second inflection point, and the at least one first inflection point may be closer to the pixel defining layer than the at least one second inflection point.

According to an embodiment, the at least one first inflection point may include a (1-1)-th inflection point and a (1-2)-th inflection point, the at least one second inflection point may include a (2-1)-th inflection point and a (2-2)-th inflection point, the first convex portion may be formed between the (1-1)-th inflection point and the (1-2)-th inflection point, and the second convex portion may be formed between the (2-1)-th inflection point and the (2-2)-th inflection point.

According to an embodiment, the first functional layer may include a hole injection layer, the second functional layer may include a hole transport layer, and the third functional layer may include an electron transport layer.

According to an embodiment, the upper surface of the third functional layer may not include an inflection point.

According to an embodiment, the lower surface of the first functional layer may have a profile according to a surface shape of the first pixel electrode, and the lower surface of the first functional layer may have a flat profile.

According to an embodiment, the base substrate may include a protrusion portion overlapping the first convex portion in a plan view and protruding in a third direction, and the first pixel electrode may be disposed on the base substrate and has a surface profile according to a shape of the protrusion portion.

In accordance with an aspect of the invention, a method of manufacturing a display device may include forming a first pixel electrode on a base substrate, forming a pixel defining layer including an opening exposing the first pixel electrode on the first pixel electrode, forming a first functional layer having an upper surface formed with first concave portions and a first convex portion formed between the first concave portions by applying and drying a first organic material on the first pixel electrode, forming a light emitting layer on the first functional layer, forming a third functional layer having an upper surface formed with a flat surface overlapping the first convex portion by applying and drying a third organic material on the light emitting layer, and forming a second pixel electrode on the third functional layer.

According to an embodiment, the drying of the first organic material may include forming the first concave portions by drying an edge area of the first organic material at a first intensity, and forming the first convex portion by drying a central area of the organic material at a second intensity less than the first intensity.

According to an embodiment, the drying of the third organic material may include forming inclined surfaces by drying an edge area of the third organic material at a third intensity between the first intensity and the second intensity, and forming the flat surface by drying a central area of the third organic material at a fourth intensity greater than the third intensity and less than the first intensity.

According to an embodiment, the method may further include forming a second functional layer having an upper surface formed with second concave portions and a second convex portion formed between the second concave portions by applying and drying a second organic material on the first functional layer.

According to an embodiment, the drying of the second organic material may include forming the second concave portions by drying an edge area of the second organic material at a fifth intensity, and forming the second convex portion by drying a central area of the second organic material at a sixth intensity, the fifth intensity may be less than the first intensity and greater than the fourth intensity, and the sixth intensity may be greater than the second intensity and less than the third intensity.

According to an embodiment, the first functional layer may include a hole injection layer, the second functional layer may include a hole transport layer, and the third functional layer may include an electron transport layer.

According to an embodiment, the method may further include forming a protrusion portion in an area corresponding to the first convex portion by partially etching the base substrate, and the first pixel electrode may be formed on the protrusion portion.

The display device and the method of manufacturing the display device according to embodiments may ensure an area in which a stack thickness of the light generation layers forming the organic light emitting unit is uniformly maintained, thereby increasing light emission efficiency.

However, the effect of the disclosure is not limited to the above-described effects, and may be variously expanded without departing from the spirit and scope of the disclosure.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device in accordance with embodiments.

FIG. 2 is a schematic circuit diagram illustrating a sub-pixel of FIG. 1.

FIGS. 3A and 3B are schematic cross-sectional views illustrating embodiments of a light emitting element of FIG. 2.

FIG. 4 is a schematic cross-sectional view of the display device including the light emitting element of FIGS. 3A and 3B.

FIG. 5A is a schematic cross-sectional view illustrating a comparative example of the sub-pixel of the display device.

FIG. 5B is a schematic plan view illustrating an emission area of FIG. 5A.

FIG. 6A is a schematic cross-sectional view illustrating an embodiment of the sub-pixel of FIG. 4.

FIG. 6B is a schematic plan view illustrating an emission area of FIG. 6A.

FIG. 7 is a schematic cross-sectional view illustrating a disposition of a first functional layer and a method of forming the first functional in accordance with an embodiment.

FIG. 8 is a schematic cross-sectional view illustrating a disposition of a second functional layer and a method of forming the second functional layer in accordance with an embodiment.

FIG. 9 is a schematic cross-sectional view illustrating a disposition of a light emitting layer and a method of forming the light emitting layer in accordance with an embodiment.

FIG. 10 is a schematic cross-sectional view illustrating a disposition of a third functional layer and a method of forming the third functional layer in accordance with an embodiment.

FIG. 11 is a schematic cross-sectional view illustrating an embodiment of the sub-pixel of FIG. 4.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments of the invention will be described in more detail with reference to the accompanying drawings.

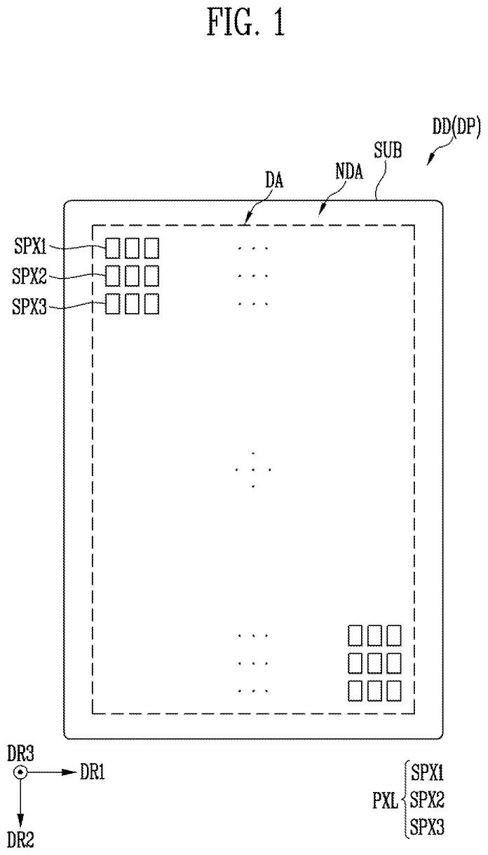

FIG. 1 is a schematic plan view illustrating a display device according to embodiments.

Referring to FIG. 1, a structure of the display device DD and a display panel DP included in the display device DD are shown based on a display area DA where an image is displayed.

For descriptive convenience, the structure of the display device DD, e.g., the display panel DP formed in the display device DD, is shown based on the display area DA where an image is displayed.

Referring to FIG. 1, the display panel DP (or the display device DD) according to an embodiment may be formed in various shapes, for example, a rectangular plate shape having two pairs of sides parallel to each other, but embodiments are not limited thereto. In case that the display panel DP is formed in a rectangular plate shape, one pair of sides of the two pairs of sides may be provided longer than the other pair of sides.

At least a portion of the display panel DP may have flexibility and may be folded at a portion having flexibility, but embodiments are not limited thereto.

The display panel DP may display an image. As the display panel DP, a display panel capable of self-emission such as an organic light emitting display panel (OLED panel) with an organic light emitting diode as a light emitting element, an ultra-small light emitting diode display panel (micro-LED or nano-LED display panel) with an ultra-small light emitting diode as a light emitting element, and a quantum dot organic light emitting display panel (QD OLED panel) with a quantum dot and an organic light emitting diode may be used. For example, as the display panel DP, a non-emission display panel such as a liquid crystal display panel (LCD panel), an electro-phoretic display panel (EPD panel), and an electro-wetting display panel (EWD panel) may be used. In case that the non-emission display panel is used as the display panel DP, the display device DD may include a backlight unit supplying light to the display panel DP.

The display panel DP may include a substrate SUB and pixels PXL disposed on the substrate SUB.

The substrate SUB may include a transparent insulating material to transmit light. The substrate SUB may be a rigid substrate or a flexible substrate.

The rigid substrate may be, for example, one of a glass substrate, a quartz substrate, a glass ceramic substrate, and a crystalline glass substrate.

The flexible substrate may be one of a film substrate and a plastic substrate including a polymeric organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, triacetate cellulose, and cellulose acetate propionate.

An area of the substrate SUB may be provided as the display area DA and pixels PXL may be disposed in the area, and a remaining area of the substrate SUB may be provided as a non-display area NDA. For example, the substrate SUB may include the display area DA including pixel areas where each pixel PXL is disposed and the non-display area NDA disposed around the display area DA (or adjacent to the display area DA).

The non-display area NDA may be positioned adjacent to the display area DA. The non-display area NDA may be disposed on at least one side of the display area DA. For example, the non-display area NDA may surround a circumference (or an edge) of the display area DA. A line unit connected to each pixel PXL and a driver connected to the line unit and driving the pixel PXL may be formed in the non-display area NDA.

The pixel PXL may include sub-pixels. For example, the pixel PXL may include a first sub-pixel SPX1, a second sub-pixel SPX2, and a third sub-pixel SPX3. The first sub-pixel SPX1, the second sub-pixel SPX2, and the third sub-pixel SPX3 may be sequentially disposed in a second direction DR2. However, embodiments are not limited thereto, and the first sub-pixel SPX1, the second sub-pixel SPX2, and the third sub-pixel SPX3 may be sequentially disposed in a first direction DR1 intersecting the second direction DR2.

The first, second, and third sub-pixels SPX1, SPX2, and SPX3 may emit light in different colors. For example, the first sub-pixel SPX1 may be a red sub-pixel emitting red light, the second sub-pixel SPX2 may be a blue sub-pixel emitting blue light, and the third sub-pixel SPX3 may be a green sub-pixel emitting green light. However, a color, a type, the number, and/or the like of the sub-pixels forming the pixel PXL are/is not limited. For example, colors of the light emitted from each of the sub-pixels SPX1, SPX2, and SPX3 may be variously changed.

According to an embodiment, the first, second, and third sub-pixels SPX1, SPX2, and SPX3 may emit light in the same color. For example, all of the first, second, and third sub-pixels SPX1, SPX2, and SPX3 may be sub-pixels emitting red light, green light, or blue light. For example, in order to implement a full-color of pixel PXL, an optical layer such as a light conversion layer and/or a color filter for converting a color of light emitted from a corresponding unit pixel may be disposed on at least a portion of the first, second, and third sub-pixels SPX1, SPX2, and SPX3.

In the following embodiment, in case that the first sub-pixel SPX1, the second sub-pixel SPX2, and the third sub-pixel SPX3 are comprehensively referred to, the first sub-pixel SPX1, the second sub-pixel SPX2, and the third sub-pixel SPX3 are referred to as sub-pixels SPX.

Pixels PXL may be provided and arranged in a matrix form along a row extending in a first direction DR1 and a column extending in a second direction DR2 intersecting the first direction DR1. An arrangement form of the pixel PXL is not limited, and the pixel PXL may be arranged in various forms. According to an embodiment, in case that pixels PXL are provided, the pixels PXL may be provided to have different areas (or sizes). For example, in a case of pixels PXL having different colors of emitted light, the pixels PXL may be formed in different areas (or sizes) or different shapes for each color.

The driver may control driving of the pixel PXL by providing a signal and a power to each pixel PXL through the line unit.

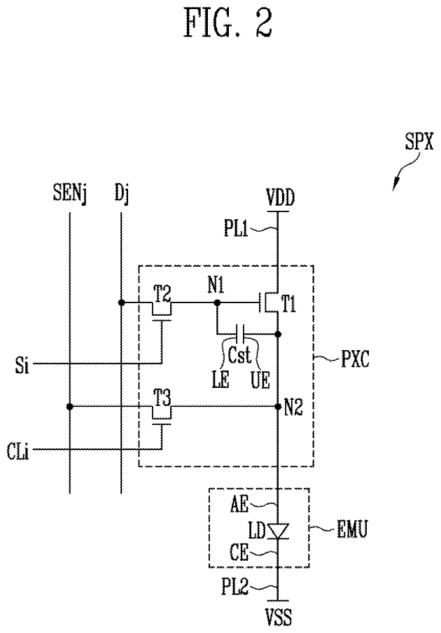

FIG. 2 is a schematic circuit diagram illustrating the sub-pixel of FIG. 1.

In FIG. 2, a sub-pixel SPX positioned in an i-th pixel row (or an i-th horizontal line) and a j-th pixel column is shown (where i and j are natural numbers).

Referring to FIGS. 1 and 2, the sub-pixel SPX may include a light emitting unit EMU that generates light of a luminance corresponding to a data signal. For example, the sub-pixel SPX may further include a pixel circuit PXC for driving the light emitting unit EMU.

The light emitting unit EMU may include a light emitting element LD connected between a first power line PL1 receiving a voltage of first driving power VDD (or first power) and a second power line PL2 receiving a voltage of second driving power VSS (or second power). For example, the light emitting unit EMU may include the light emitting element LD including a first pixel electrode AE connected to the first driving power VDD via the pixel circuit PXC and the first power line PL1 and a second pixel electrode CE connected to the second driving power VSS via the second power line PL2. The first pixel electrode AE may be an anode, and the second pixel electrode CE may be a cathode. The first driving power VDD and the second driving power VSS may have different potentials. At this time, a potential difference between the first driving power VDD and the second driving power VSS may be set to be higher than or equal to a threshold voltage of the light emitting element LD during an emission period of the sub-pixel SPX.

In case that the sub-pixel SPX is positioned in the i-th pixel row and the j-th pixel column in the display area DA, the pixel circuit PXC of the sub-pixel SPX may be electrically connected to an i-th scan line Si and a j-th data line Dj. For example, the pixel circuit PXC may be electrically connected to an i-th control line CLi and a j-th sensing line SENj.

The above-described pixel circuit PXC may include first, second, and third transistors T1, T2, and T3 and a storage capacitor Cst.

The first transistor T1 may be a driving transistor for controlling a driving current applied to the light emitting element LD, and may be electrically connected between the first driving power VDD and the light emitting element LD. For example, a first terminal of the first transistor T1 may be electrically connected to the first driving power VDD through the first power line PL1, a second terminal of the first transistor T1 may be electrically connected to a second node N2, and a gate electrode of the first transistor T1 may be electrically connected to a first node N1. The first transistor T1 may control an amount of the driving current applied from the first driving power VDD to the light emitting element LD through the second node N2 according to a voltage applied to the first node N1. In an embodiment, the first terminal of the first transistor T1 may be a drain electrode, and the second terminal of the first transistor T1 may be a source electrode, but embodiments are not limited thereto. According to an embodiment, the first terminal may be a source electrode and the second terminal may be a drain electrode.

The second transistor T2 may be a switching transistor that selects the sub-pixel SPX in response to a scan signal and activates the sub-pixel SPX, and may be electrically connected between the data line Dj (for example, the j-th data line) and the first node N1. A first terminal of the second transistor T2 may be electrically connected to the data line Dj, a second terminal of the second transistor T2 may be connected to the first node N1 (or the gate electrode of the first transistor T1), and a gate electrode of the second transistor T2 may be electrically connected to the scan line Si (or the i-th scan line). The first terminal and the second terminal of the second transistor T2 may be different terminals, and for example, in case that the first terminal is a drain electrode, a second terminal may be a source electrode.

The second transistor T2 may be turned on in case that a scan signal of a gate-on voltage (for example, a high level voltage) is supplied from the scan line Si, to electrically connect the data line Dj and the first node N1. The first node N1 may be a point where the second terminal of the second transistor T2 and the gate electrode of the first transistor T1 are connected, and the second transistor T2 may transfer a data signal to the gate electrode of the first transistor T1.

The third transistor T3 may receive a sensing signal through the sensing line SENj by electrically connecting the first transistor T1 to the sensing line SENj (for example, the j-th sensing line), and detect a characteristics of the sub-pixel SPX including a threshold voltage of the first transistor T1 by using the sensing signal. Information on the characteristic of the sub-pixel SPX may be used to convert image data so that a characteristic deviation between the sub-pixels SPX may be compensated. A second terminal of the third transistor T3 may be electrically connected to the second terminal of the first transistor T1, a first terminal of the third transistor T3 may be electrically connected to the sensing line SENj, and a gate electrode of the third transistor T3 may be electrically connected to the control line CLi (for example, the i-th control line). The first terminal may be a drain electrode, and the second terminal may be a source electrode.

The third transistor T3 may be an initialization transistor capable of initializing the second node N2, and may be turned on in case that a sensing control signal is supplied from the control line CLi to transfer a voltage of initialization power to the second node N2. Accordingly, the storage capacitor Cst electrically connected to the second node N2 may be initialized.

The storage capacitor Cst may include a lower electrode LE (or a first storage electrode) and an upper electrode UE (or a second storage electrode). The lower electrode LE may be electrically connected to the first node N1 and the upper electrode UE may be electrically connected to the second node N2. The storage capacitor Cst may charge a data voltage corresponding to the data signal supplied to the first node N1 during one frame period. Accordingly, the storage capacitor Cst may store a voltage corresponding to a difference between a voltage of the gate electrode of the first transistor T1 and a voltage of the second node N2.

In FIG. 2, an embodiment in which all of the first, second, and third transistors T1, T2, and T3 are N-type transistors is disclosed, but embodiments are not limited thereto. For example, at least one of the above-described first, second, and third transistors T1, T2, and T3 may be changed (or modified) to a P-type transistor. A structure of the pixel circuit PXC may be variously modified and implemented.

In the following embodiment, for convenience of description, a width direction (e.g., an X-axis direction, or a horizontal direction) on a plane is indicated as the first direction DR1, a height direction (e.g., a Y-axis direction, or a vertical direction) on the plane is indicated as the second direction DR2, and a vertical direction on a cross section is indicated as a third direction DR3.

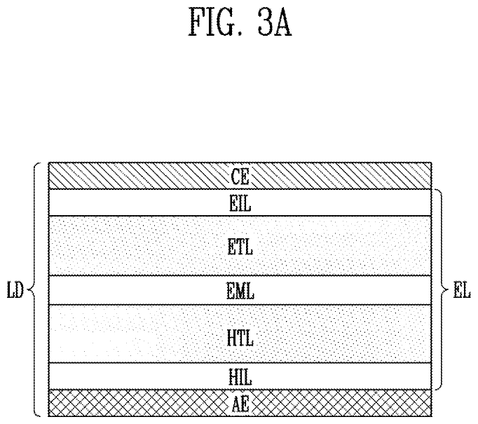

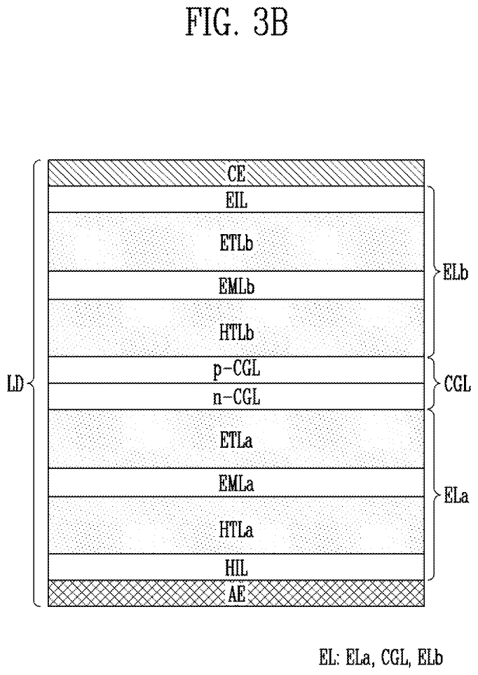

FIGS. 3A and 3B are schematic cross-sectional views illustrating embodiments of the light emitting element of FIG. 2.

Referring to FIG. 3A, the light emitting element LD may include the first pixel electrode AE, an organic light emitting unit EL, and the second pixel electrode CE that are sequentially stacked.

In an embodiment, the organic light emitting unit EL may be disposed on the first pixel electrode AE. The organic light emitting unit EL may have a multilayer thin film structure including light generation layers. The organic light emitting unit EL may include a hole injection layer HIL, a hole transport layer HTL, a light emitting layer EML, an electron transport layer ETL, and an electron injection layer EIL that are sequentially stacked.

The hole injection layer HIL may be an organic layer disposed between the first pixel electrode AE and the hole transport layer HTL to facilitates injection of a hole from the first pixel electrode AE into the light emitting layer EML. The hole transport layer HTL may be disposed between the hole injection layer HIL and the first pixel electrode AE to receive the hole from the first pixel electrode AE and transport the hole to the light emitting layer EML.

The electron injection layer EIL may be disposed between the electron transport layer ETL and the second pixel electrode CE. The electron transport layer ETL may be disposed on the light emitting layer EML to receive an electron from the second pixel electrode CE and transport the electron to the light emitting layer EML.

The light emitting layer EML may be an area in which light is generated by combination of the electron and the hole supplied from the first pixel electrode AE and the second pixel electrode CE. The light emitting layer EML may include an organic light emitting material such as a high molecular organic material or low molecular organic material that emits light of a color. For example, the light emitting layer EML may include an organic material emitting blue light. However, embodiments are not limited thereto. In an example, the light emitting layer EML may include an organic material emitting red light or green light, or may include an inorganic material or a quantum dot.

In an embodiment, the second pixel electrode CE may be integrally formed. The second pixel electrode CE may be disposed on the organic light emitting unit EL. The second pixel electrode CE may be integrally formed in the light emitting elements.

Referring to FIG. 3B, the light emitting element LD may include the first pixel electrode AE, the organic light emitting unit EL, and the second pixel electrode CE.

The organic light emitting unit EL may include the light generation layers. In an example, the organic light emitting unit EL may include a first organic light emitting unit ELa, a charge generation layer CGL, and a second organic light emitting unit ELb. The first pixel electrode AE, the first organic light emitting unit ELa, the charge generation layer CGL, the second organic light emitting unit ELb, and the second pixel electrode CE may be sequentially stacked.

The first organic light emitting unit ELa may be formed in a structure in which the hole injection layer HIL, a first hole transport layer HTLa, a first organic light emitting layer EMLa, and a first electron transport layer ETLa are sequentially stacked. The second organic light emitting unit ELb may be formed in a structure in which a second hole transport layer HTLb, a second organic light emitting layer EMLb, a second electron transport layer ETLb, and the electron injection layer EIL are sequentially stacked.

In an embodiment, a buffer layer may be disposed on the first organic light emitting layer EMLa and the second organic light emitting layer EMLb. The buffer layer may include an electron transporting compound.

The charge generation layer CGL may function to supply a charge to the first organic light emitting unit ELa and the second organic light emitting unit ELb. The charge generation layer CGL may be provided by including an n-type charge generation layer n-CGL for supplying the charge to the first organic light emitting unit ELa and a p-type charge generation layer p-CGL for supplying the hole to the second organic light emitting unit ELb. At this time, the n-type charge generation layer n-CGL may be provided by including a metal material as a dopant.

In FIG. 3B, the two organic light emitting units ELa and ELb of the light emitting element LD may be stacked, but embodiments are not limited thereto. For example, three or four or more organic light emitting units may be stacked in the light emitting element LD.

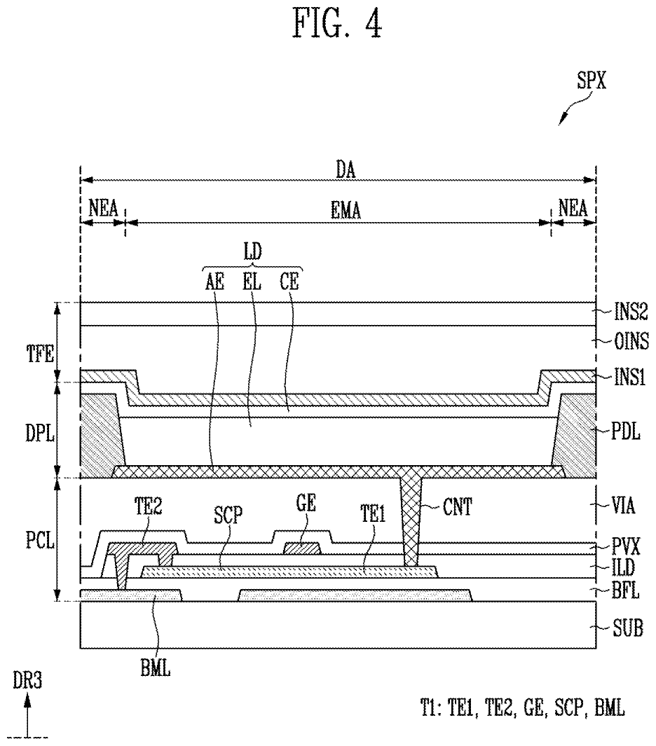

FIG. 4 is a schematic cross-sectional view of the display device including the light emitting element of FIGS. 3A and 3B.

Referring to FIG. 4, a stack structure of the sub-pixel SPX is shown in a simplified manner, such as showing each electrode as a single-layer electrode and each insulating layer as a single-layer insulating layer, but embodiments are not limited thereto.

The sub-pixel SPX shown in FIG. 4 may indicate one of the first sub-pixel SPX1, second sub-pixel SPX2, and third sub-pixel SPX3 shown in FIG. 1, and may also be applied to other pixels.

The sub-pixel SPX may be disposed in the display area DA. The sub-pixel SPX may include an emission area EMA and a non-emission area NEA. The sub-pixel SPX may include the substrate SUB, a pixel circuit layer PCL, a display element layer DPL, and an encapsulation layer TFE.

The substrate SUB may include a transparent insulating material to transmit light. The substrate SUB may be a rigid substrate or a flexible substrate.

Circuit elements (for example, the first, second, and third transistors T1, T2, and T3 of FIG. 2) and signal lines electrically connected to the circuit elements may be disposed in the pixel circuit layer PCL. The light emitting element LD electrically connected to each of the circuit elements may be disposed in the display element layer DPL.

The pixel circuit layer PCL may be disposed on the substrate SUB. The pixel circuit layer PCL may include a lower auxiliary electrode BML, a buffer layer BFL, the first transistor T1, an interlayer insulating layer ILD, a protective layer PVX, and a via layer VIA. In FIG. 4, only the first transistor T1 among the circuit elements is shown for descriptive convenience.

The lower auxiliary electrode BML may be disposed on the substrate SUB. The lower auxiliary electrode BML may function as a path through which an electrical signal is transferred. In an example, the lower auxiliary electrode BML may overlap the first transistor T1.

The buffer layer BFL may be disposed on the substrate SUB. The buffer layer BFL may cover the lower auxiliary electrode BML. The buffer layer BFL may prevent an impurity from being diffused from an outside. The buffer layer BFL may prevent the impurity from being diffused into the first transistor T1 disposed on the substrate SUB and improve flatness of the substrate SUB. The buffer layer BFL may be formed as a single layer or may be formed as multiple layers. The buffer layer BFL may be an inorganic insulating layer including an inorganic material. The inorganic insulating layer may include, for example, at least one of metal oxides such as silicon nitride (SiNₓ), silicon oxide (SiOₓ), silicon oxynitride (SiOₓN_{y}), and aluminum oxide (AlOₓ). In case that the buffer layer BFL is formed as multiple layers, each layer may be formed of the same material or different materials. In another example, the buffer layer BFL may be omitted in some cases.

The first transistor T1 may include a semiconductor pattern layer SCP, a gate electrode GE, a first terminal TE1, and a second terminal TE2. The first terminal TE1 may be any one of a source electrode and a drain electrode, and the second terminal TE2 may be the other electrode. For example, in case that the first terminal TE1 is the drain electrode, the second terminal TE2 may be the source electrode.

The semiconductor pattern layer SCP may be provided and/or formed on the buffer layer BFL. The semiconductor pattern layer SCP may include a first contact area contacting the first terminal TE1, a second contact area contacting the second terminal TE2, and a channel area between the first contact area and the second contact area. The channel area may overlap the gate electrode GE of the first transistor T1. The semiconductor pattern layer SCP may be a semiconductor pattern layer formed of amorphous silicon, polysilicon, low-temperature polysilicon, an oxide semiconductor, or an organic semiconductor. The channel area may be, for example, a semiconductor pattern layer that is not doped with an impurity, and may be an intrinsic semiconductor. The first contact area and the second contact area may be a semiconductor pattern layer doped with an impurity. In an example, the first terminal TE1 may be electrically connected to the light emitting element LD through a separate connection means such as a bridge electrode.

The interlayer insulating layer ILD may be provided and/or formed on the semiconductor pattern layer SCP. The interlayer insulating layer ILD may be an inorganic insulating layer including an inorganic material. The interlayer insulating layer ILD and the buffer layer BFL may include the same material. The interlayer insulating layer ILD may include one or more materials selected from materials such as a configuration material of the buffer layer BFL. In an example, the interlayer insulating layer ILD may be formed as an organic insulating layer including an organic material. The interlayer insulating layer ILD may be formed as a single layer, but may be formed as a multiple layers at least double or more layers.

The gate electrode GE may be provided and/or formed on the interlayer insulating layer ILD to correspond to (or to overlap) the channel area of the semiconductor pattern layer SCP. The gate electrode GE may be disposed on the interlayer insulating layer ILD and overlap the channel area of the semiconductor pattern layer SCP. The gate electrode GE may be formed in a single layer of a material selected from a group consisting of copper (Cu), molybdenum (Mo), tungsten (W), aluminum neodymium (AlNd), titanium (Ti), aluminum (Al), silver (Ag), and an alloy thereof alone or a mixture thereof, or may be formed in a double layer or multilayer structure of a molybdenum (Mo), titanium (Ti), copper (Cu), aluminum (Al), or silver (Ag), which is a low-resistance material, to reduce a line resistance.

The second terminal TE2 may be provided and/or formed on the interlayer insulating layer ILD to contact the second contact area of the semiconductor pattern layer SCP through a contact hole passing through the interlayer insulating layer ILD. The second terminal TE2 may contact the lower auxiliary electrode BML through a contact hole passing through the interlayer insulating layer ILD and the buffer layer BFL. The first terminal TE1 and the second terminal TE2 may include the same material as the gate electrode GE, or may include one or more materials selected from materials such as a configuration material of the gate electrode GE.

In the above-described embodiment, the first terminal TE1 of the first transistor T1 may be disposed in an area adjacent to the channel area of the semiconductor pattern layer SCP, and the second terminal TE2 may be a separate electrode connected (e.g., electrically connected) to the semiconductor pattern layer SCP through the contact hole passing through the interlayer insulating layer ILD, but embodiments are not limited thereto. According to an embodiment, the first terminal TE1 may be connected (e.g., electrically connected) to the semiconductor pattern layer SCP through a contact hole passing through the interlayer insulating layer ILD, and the second terminal TE2 may be disposed in an area adjacent to the channel area of the semiconductor pattern layer SCP.

The protective layer PVX may be provided and/or formed on the first transistor T1. The protective layer PVX may be formed in a form including an insulating layer disposed on an organic insulating layer or an organic insulating layer disposed on an inorganic insulating layer. The inorganic insulating layer may include, for example, at least one of metal oxides such as silicon oxide (SiOₓ), silicon nitride (SiNₓ), silicon oxynitride (SiOₓN_{y}), and aluminum oxide (AlOₓ). The organic insulating layer may include, for example, at least one of acrylic resin (e.g., polyacrylate resin), epoxy resin, phenol resin, polyamide resin, polyimide resin, unsaturated polyesters resin, poly-phenylen ether resin, poly-phenylene sulfide resin, and benzocyclobutene resin.

The via layer VIA may be provided and/or formed on (e.g., entirely on) the protective layer PVX. The via layer VIA may be an inorganic insulating layer including an inorganic material or an organic insulating layer including an organic material.

Each of the interlayer insulating layer ILD, the protective layer PVX, and the via layer VIA may be partially opened to include a contact portion CNT (or a contact hole). The first terminal TE1 may be connected (e.g., electrically connected) to the light emitting element LD through the contact portion CNT.

The display element layer DPL may be provided and/or formed on the via layer VIA. The display element layer DPL may include the light emitting element LD and a pixel defining layer PDL.

The light emitting element LD may include the first pixel electrode AE, the organic light emitting unit EL, and the second pixel electrode CE. The light emitting element LD may be connected (e.g., electrically connected) to a pixel circuit (for example, the pixel circuit PXC of FIG. 2) of a corresponding pixel.

The first pixel electrode AE may be provided and/or formed on the via layer VIA of the corresponding pixel. The first pixel electrode AE may be an anode electrode of the light emitting element LD.

The first pixel electrode AE may be connected (e.g., electrically connected) to the first terminal TE1 through a corresponding contact portion CNT.

Each of the first pixel electrodes AE may be formed of a conductive material (or substance). The conductive material may include an opaque metal. The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, a material of each of the first pixel electrodes AE is not limited to the above-described embodiment. According to an embodiment, the first pixel electrode AE may include a transparent conductive material (or substance). The transparent conductive material (or substance) may include a conductive oxide such as indium tin oxide (ITO), indium zinc oxide (IZO), zinc oxide (ZnOₓ), indium gallium zinc oxide (IGZO), indium tin zinc oxide (ITZO), a conductive polymer such as poly(3,4-ethylenedioxythiophene) (PEDOT), and the like. In case that the first pixel electrode AE includes the transparent conductive material (or substance), a separate conductive layer formed of an opaque metal for reflecting light emitted from the organic light emitting unit EL in an image display direction of the display device (for example, the display device DD of FIG. 1) (or toward the encapsulation layer TFE) may be added. The first pixel electrode AE may be positioned in the emission area EMA.

The pixel defining layer PDL may define (or partition) the emission area EMA. The pixel defining layer PDL may be an organic insulating layer formed of an organic material. In an embodiment, the pixel defining layer PDL may include a light absorbing material or may be coated with a light absorbing material to absorb light introduced (or transmitted) from the outside. For example, the pixel defining layer PDL may include a carbon-based black pigment. However, embodiments are not limited thereto.

The pixel defining layer PDL may be partially opened to include an opening exposing an area of the first pixel electrode AE, and may protrude in a third direction DR3 from the via layer VIA along a circumference of the emission area EMA. The pixel defining layer PDL may be disposed on the via layer VIA to define an area where the organic light emitting unit EL contacts the first pixel electrode AE. The organic light emitting unit EL may be disposed on the first pixel electrode AE exposed by the opening of the pixel defining layer PDL.

The organic light emitting unit EL may be positioned above the first pixel electrode AE and above the pixel defining layer PDL in the opening of the pixel defining layer PDL, but embodiments are not limited thereto, and the organic light emitting unit EL may be positioned only above the first pixel electrode AE in the opening of the pixel defining layer PDL.

The organic light emitting unit EL may have a multilayer thin film structure including a light generation layer that generates light. The organic light emitting unit EL may emit one of red light, green light, and blue light, but embodiments are not limited thereto. The organic light emitting unit EL may have a multilayer thin film structure including light generation layers. The organic light emitting unit EL may include a hole injection layer for injecting a hole, a hole transport layer having an excellent hole transport property and for increasing a chance of recombination of a hole and an electron by suppressing a movement of an electron that is not combined in the light generation layer, the light generation layer for emitting light by the recombination of the injected electron and hole, a hole blocking layer for suppressing a movement of a hole that is not combined in the light generation layer, an electron transport layer for smoothly transporting the electron to the light generation layer, and an electron injection layer for injecting the electron. The organic light emitting unit EL may emit light based on an electrical signal provided from the first pixel electrode AE and the second pixel electrode CE.

The second pixel electrode CE may be disposed on the organic light emitting unit EL and the pixel defining layer PDL. The second pixel electrode CE may be formed in a plate shape over the entire area of the display area DA.

The second pixel electrode CE may be a thin film metal layer having a thickness sufficient to transmit the light emitted from each organic light emitting unit EL. The second pixel electrode CE may be formed of a metal material or a transparent conductive material to have a relatively thin thickness. The second pixel electrode CE may include at least one of various transparent conductive materials including indium tin oxide, indium zinc oxide, indium tin zinc oxide, aluminum zinc oxide, gallium zinc oxide, zinc tin oxide, or gallium tin oxide, and may be implemented as substantially transparent or translucent to satisfy a light transmittance. Accordingly, light emitted from the light emitting layer EML positioned under the second pixel electrode CE may pass through the second pixel electrode CE and may be emitted in an upper direction of the encapsulation layer TFE.

The encapsulation layer TFE may be provided and/or formed on the entire second pixel electrode CE.

The encapsulation layer TFE may include a first insulating layer INS1, an organic insulating layer OINS, and a second insulating layer INS2 sequentially disposed on the second pixel electrode CE. The first insulating layer INS1 may be positioned on the display element layer DPL (or the second pixel electrode CE) and may be disposed in (e.g., entirely in) the display area DA.

Each of the first insulating layer INS1 and the second insulating layer INS2 may be formed of an inorganic layer including an inorganic material, and the organic insulating layer OINS may be formed of an organic layer including an organic material.

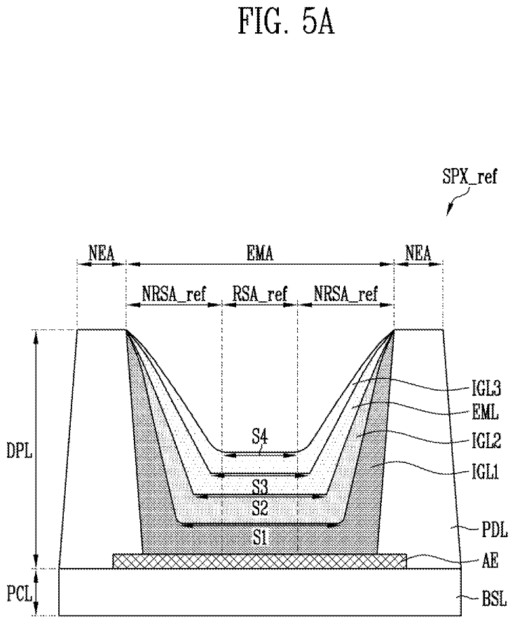

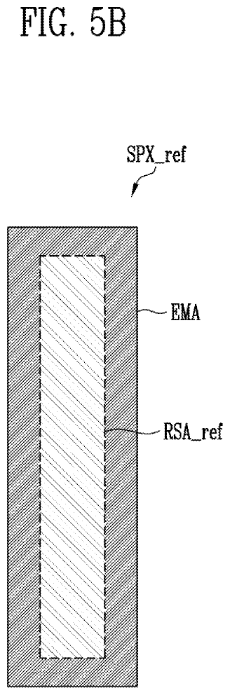

FIG. 5A is a schematic cross-sectional view illustrating a comparative example of the sub-pixel of the display device. FIG. 5B is a schematic plan view illustrating the emission area of FIG. 5A.

Referring to FIG. 5A, a comparison sub-pixel SPX_ref may include the pixel circuit layer PCL and the display element layer DPL disposed on the pixel circuit layer PCL. The pixel circuit layer PCL may include transistors and signal lines connected to the transistors. The display element layer DPL may be disposed on a base substrate BSL (or the via layer) of the pixel circuit layer PCL.

The first pixel electrode AE of the comparison sub-pixel SPX_ref may be disposed on the base substrate BSL. The comparison sub-pixel SPX_ref may include light generation layers disposed in the third direction DR3 on the first pixel electrode AE. The comparison sub-pixel SPX_ref may include a first functional layer IGL1, a second functional layer IGL2, the light emitting layer EML, and a third functional layer IGL3 sequentially disposed in the third direction DR3 on the first pixel electrode AE.

The first functional layer IGL1, the second functional layer IGL2, the light emitting layer EML, and the third functional layer IGL3 of the comparison sub-pixel SPX_ref may be sequentially deposited on the first pixel electrode AE.

The first functional layer IGL1 may be deposited on the pixel defining layer PDL and the first pixel electrode AE to cover a side surface of the pixel defining layer PDL and the first pixel electrode AE. The first functional layer IGL1 may include an outer surface (or upper surface) facing an opposite direction of an inner surface (or lower surface) contacting the first pixel electrode AE and the pixel defining layer PDL. The outer surface (or upper surface) of the first functional layer IGL1 may include an inclined surface inclined along the side surface of the pixel defining layer PDL, and a first flat surface S1 connected to the first inclined surface. The first functional layer IGL1 may be the hole injection layer HIL of the light emitting element.

The second functional layer IGL2 may be disposed on the first functional layer IGL1 and deposited to cover the first functional layer IGL1. The second functional layer IGL2 may include an outer surface (or upper surface) facing in an opposite direction of an inner surface (or lower surface) contacting the first functional layer IGL1. The outer surface (or upper surface) may be opposite to the inner surface (or lower surface). The inner surface (or lower surface) of the second functional layer IGL2 may have a profile according to the outer surface (or upper surface) of the first functional layer IGL1. The outer surface (or upper surface) of the second functional layer IGL2 may include a second inclined surface inclined along the first inclined surface of the first functional layer IGL1 and a second flat surface S2 connected to the second inclined surface. A width of the second flat surface S2 of the second functional layer IGL2 may be less than a width of the first flat surface S1 of the first functional layer IGL1 by a thickness of the second functional layer IGL2. The first functional layer IGL1 may be the hole transport layer HTL of the light emitting element.

The light emitting layer EML may be disposed on the second functional layer IGL2 and deposited to cover the second functional layer IGL2. The light emitting layer EML may include an outer surface (or upper surface) facing an opposite direction of an inner surface (or lower surface) contacting the second functional layer IGL2. The inner surface (or lower surface) of the light emitting layer EML may have a profile according to the outer surface (or upper surface) of the second functional layer IGL2. The outer surface (or upper surface) of the light emitting layer EML may include a third inclined surface inclined along the second inclined surface of the second functional layer IGL2 and a third flat surface S3 connected to the third inclined surface. A width of the third flat surface S3 of the light emitting layer EML may be less than the width of the second flat surface S2 of the second functional layer IGL2 by a thickness of the light emitting layer EML. The light emitting layer EML may be an area in which light is generated by the combination of the electron and the hole.

The third functional layer IGL3 may be disposed on the light emitting layer EML and deposited to cover the light emitting layer EML. The third functional layer IGL3 may include an outer surface (or upper surface) facing an opposite direction of an inner surface (or lower surface) contacting the light emitting layer EML. The inner surface (or lower surface) of the third functional layer IGL3 may have a profile according to the outer surface (or upper surface) of the light emitting layer EML. The outer surface (or upper surface) of the third functional layer IGL3 may include a fourth inclined surface inclined along the third inclined surface of the light emitting layer EML and a fourth flat surface S4 connected to the fourth inclined surface and disposed on the third flat surface S3 of the light emitting layer EML. A width of the fourth flat surface S4 of the third functional layer IGL3 may be less than the width of the third flat surface S3 of the light emitting layer EML by a thickness of the third functional layer IGL3. The third functional layer IGL3 may be the electron transport layer ETL of the light emitting element.

In order to increase light emission efficiency of the display device, an area where the hole and the electron are balanced may be required to be ensured, and the area where the hole and the electron are balanced may be an area where a thickness of the light generation layers forming the organic light emitting unit is maintained constant.

Referring to FIGS. 5A and 5B, an area where a stack thickness of the first, second, and third functional layers IGL1, IGL2, and IGL3 and the light emitting layer EML of the comparison sub-pixel SPX_ref is maintained constant corresponds to the fourth flat surface S4.

A resonance satisfactory area RSA_ref may be an area of the light emitting layer EML corresponding to the fourth flat surface S4 and may include the area in which the hole and the electron are balanced. A resonance unsatisfactory area NRSA_ref may be an area excluding the resonance satisfactory area RSA_ref from the emission area EMA, and may be an area where light is not normally emitted due to constructive interference of the light emitted from the light emitting layer EML. The resonance satisfactory area RSA_ref is limited to an area corresponding to an area of the fourth flat surface S4 of the third functional layer IGL3 by a stack structure of the first, second, and third functional layers IGL1, IGL2, and IGL3 and the light emitting layer EML. Accordingly, a size of the resonance satisfactory area RSA_ref may be less than a size of the resonance unsatisfactory area NRSA_ref. Therefore, the display device may be required to ensure the area where the hole and the electron are balanced in order to increase the light emission efficiency. For example, the display device may be required to ensure an area where the stack thickness of the light generation layers is maintained constant in the organic light emitting unit (for example, the organic light emitting unit EL of FIG. 4).

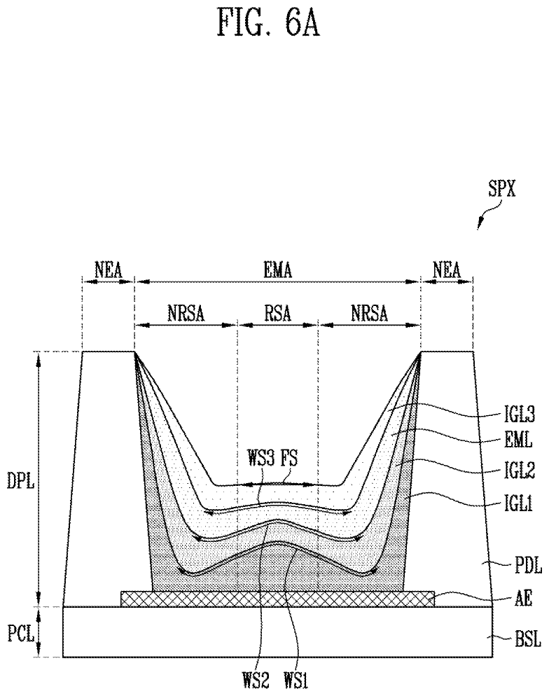

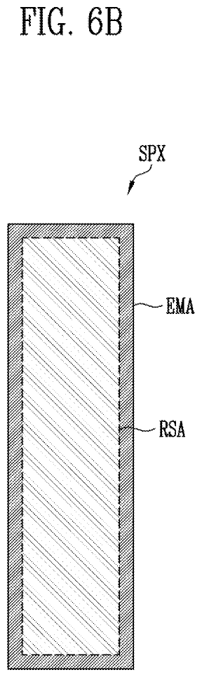

FIG. 6A is a schematic cross-sectional view illustrating an embodiment of the sub-pixel of FIG. 4. FIG. 6B is a schematic plan view illustrating the emission area of FIG. 6A.

Referring to FIG. 6A, the sub-pixel SPX may include the pixel circuit layer PCL and the display element layer DPL disposed on the pixel circuit layer PCL. The pixel circuit layer PCL may include transistors and signal lines connected to the transistors. The display element layer DPL may be disposed on the base substrate BSL (for example, the via layer VIA of FIG. 4) of the pixel circuit layer PCL.

In an embodiment, the first pixel electrode AE may be disposed on the base substrate BSL. In the sub-pixel SPX, the light generation layers forming the organic light emitting unit (for example, the organic light emitting unit EL of FIG. 4) may be sequentially disposed in the third direction DR3 on the first pixel electrode AE. In an example, the first functional layer IGL1, the second functional layer IGL2, the light emitting layer EML, and the third functional layer IGL3 forming the organic light emitting unit may be sequentially disposed in the direction DR3 on the first pixel electrode AE.

In an embodiment, the first functional layer IGL1, the second functional layer IGL2, the light emitting layer EML, and the third functional layer IGL3 may be sequentially deposited on the first pixel electrode AE.

In an embodiment, the first functional layer IGL1 may be disposed on the pixel defining layer PDL and the first pixel electrode AE and deposited to cover the side surface of the pixel defining layer PDL and the first pixel electrode AE. The first functional layer IGL1 may be disposed between the first pixel electrode AE and the second functional layer IGL2 and may be an organic layer that facilitates injection of the hole from the first pixel electrode AE into the light emitting layer EML. The first functional layer IGL1 may be the hole injection layer HIL.

In an embodiment, the first functional layer IGL1 may include an outer surface (or upper surface) facing in an opposite direction of an inner surface (or lower surface) contacting the first pixel electrode AE and the pixel defining layer PDL. For example, the outer surface (or upper surface) may be opposite to the inner surface (or lower surface).

In an embodiment, the inner surface (or lower surface) of the first functional layer IGL1 may have a profile according to a shape of the pixel defining layer PDL and the first pixel electrode AE. In an example, the inner surface (or lower surface) of the first functional layer IGL1 contacting the first pixel electrode AE may have a flat surface.

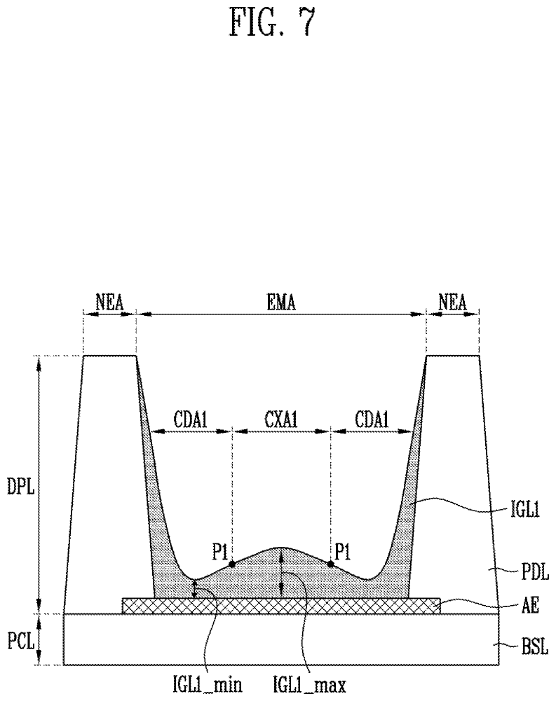

In an embodiment, the outer surface (or upper surface) of the first functional layer IGL1 may include an inclined surface inclined according to a shape of the side surface of the pixel defining layer PDL and a first curved surface WS1 connected to the inclined surface. In an example, the first curved surface WS1 may include at least one convex portion. The at least one convex portion may correspond to a central area of the emission area EMA. In an example, the first curved surface WS1 may include first concave portions (for example, a first concave portion CDA1 of FIG. 7) and a first convex portion (for example, a first convex portion CXA1 of FIG. 7) disposed between the first concave portions. In an example, a stack thickness of the first functional layer IGL1 according to the first curved surface WS1 may not be constant for each position along a direction intersecting the third direction DR3. A disposition and a design process of the first functional layer IGL1 are described later with reference to FIG. 7.

In an embodiment, the second functional layer IGL2 may be disposed on the first functional layer IGL1 and deposited to cover the first functional layer IGL1. The second functional layer IGL2 may be disposed between the first functional layer IGL1 and the light emitting layer EML to receive the hole from the first pixel electrode AE and transport the hole to the light emitting layer EML. In an example, the second functional layer IGL2 may be the hole transport layer HTL.

In an embodiment, the second functional layer IGL2 may include an outer surface (or upper surface) facing in an opposite direction of an inner surface (or lower surface) contacting the first functional layer IGL1. The outer surface (or upper surface) may be opposite to the inner surface (or lower surface).

In an embodiment, the inner surface (or lower surface) of the second functional layer IGL2 may have a profile according to a shape of the outer surface (or upper surface) of the first functional layer IGL1. In an example, the inner surface (or lower surface) of the second functional layer IGL2 may correspond to the first curved surface WS1 of the first functional layer IGL1.

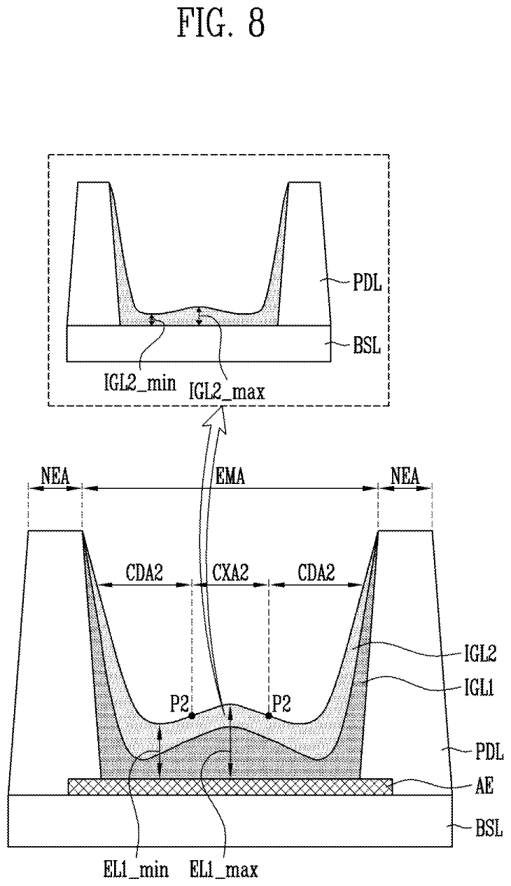

In an embodiment, the outer surface (or upper surface) of the second functional layer IGL2 may include an inclined surface inclined along the inclined surface of the first functional layer IGL1 and a second curved surface WS2 connected to the inclined surface. The second curved surface WS2 may include at least one convex portion. The at least one convex portion may correspond to the central area of the emission area EMA. In an example, the second curved surface WS2 may include second concave portions (for example, a second concave portion CDA2 of FIG. 8) and a second convex portion (for example, a second convex portion CXA2 of FIG. 8) disposed between the second concave portions. In an example, the second convex portion CXA2 may overlap the first convex portion CXA1 in a cross-sectional view.

In an embodiment, the second curved surface WS2 of the second functional layer IGL2 may be disposed in consideration of a shape of the first curved surface WS1 of the first functional layer IGL1. In an example, a difference between the lowest height of the second concave portions and the highest height of the second convex portion may be less than a difference between the lowest height of the first concave portions and the highest height of the first convex portion of the first functional layer IGL1, but embodiments are not limited thereto.

In an embodiment, a stack thicknesses of the first and second functional layers IGL1 and IGL2 may not be constant according to a position along a direction intersecting the third direction DR3. In an example, a difference of the stack thickness of the first and second functional layers IGL1 and IGL2 at each position may be less than a thickness difference of the first functional layer IGL1 at each position, but embodiments are not limited thereto. For example, the difference of the stack thickness of the first and second functional layers IGL1 and IGL2 at each position may be greater than the thickness difference of the first functional layer IGL1 at each position. A disposition and a design process of the second functional layer IGL2 are described later with reference to FIG. 8.

In an embodiment, the light emitting layer EML may be disposed on the second functional layer IGL2 and deposited to cover the second functional layer IGL2. The light emitting layer EML may be disposed between the second functional layer IGL2 and the third functional layer IGL3 and may be an area where the light is generated by the combination of the electron and the hole supplied from the first pixel electrode AE and the second pixel electrode (for example, the second pixel electrode CE of FIG. 4).

In an embodiment, the light emitting layer EML may include the outer surface (or upper surface) facing the opposite direction of the inner surface (or lower surface) contacting the second functional layer IGL2.

In an embodiment, the inner surface (or lower surface) of the light emitting layer EML may have a profile according to a shape of the outer surface (or upper surface) of the second functional layer IGL2. In an example, the inner surface (or lower surface) of the light emitting layer EML may correspond to the second curved surface WS2 of the second functional layer IGL2.

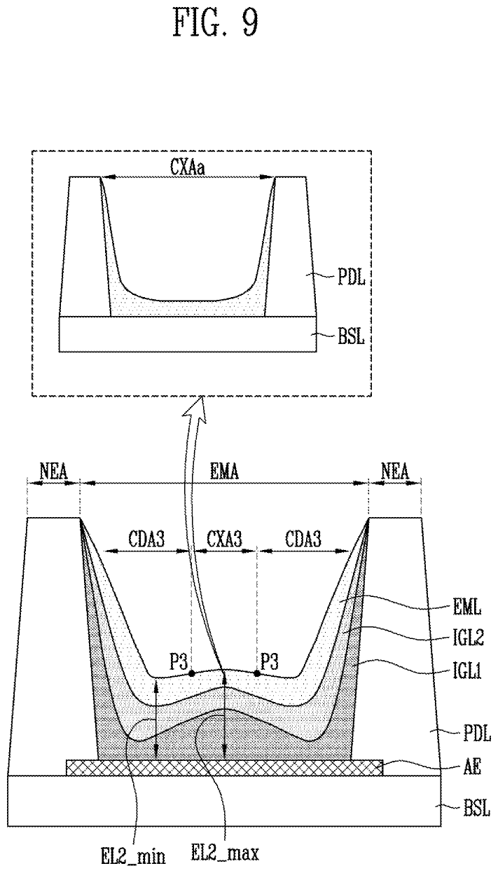

In an embodiment, the outer surface (or upper surface) of the light emitting layer EML may include an inclined surface on which the second functional layer IGL2 is inclined along the inclined surface and a third curved surface WS3 connected to the inclined surface. The third curved surface WS3 may include at least one convex portion. The at least one convex portion may correspond to the central area of the emission area EMA. In an example, the third curved surface WS3 may include third concave portions (for example, a third concave portion CDA3 of FIG. 9) and a third convex portion (for example, a third convex portion CXA3 of FIG. 9) disposed between the third concave portions. In an example, the third convex portion CXA3 may overlap the first convex portion (for example, the first convex portion CXA1 of FIG. 7) of the first functional layer IGL1 and the second convex portion (for example, the second convex portion CXA2 of FIG. 8) of the second functional layer IGL2 in a cross-sectional view.

In an embodiment, the third curved surface WS3 of the second functional layer IGL3 may be formed in consideration of a shape of the second curved surface WS2 of the second functional layer IGL2. In an example, a difference between the lowest height of the third concave portions and the highest height of the third convex portion may be less than the difference between the lowest height of the second concave portions and the highest height of the second convex portion of the second functional layer IGL2.

In an embodiment, a stack thicknesses of the first and second functional layers IGL1 and IGL2 and the light emitting layer EML may not be constant according to a position along the direction intersecting the third direction DR3. A difference of the stack thickness of the first and second functional layers IGL1 and IGL2 and the light emitting layer EML at each position may be less than the difference of the stack thickness of the first and second functional layers IGL1 and IGL2 at each position. The light emitting layer EML, which allows the difference of the stack thickness of the first and second functional layers IGL1 and IGL2 and the light emitting layer EML at each position to be less than the difference of the stack thickness of the first and second functional layers IGL1 and IGL2 at each position, may be disposed. A disposition and a design process of the light emitting layer EML are described later with reference to FIG. 9.

In an embodiment, the third functional layer IGL3 may be disposed on the light emitting layer EML and deposited to cover the light emitting layer EML. The third functional layer IGL3 may be disposed between the light emitting layer EML and the second pixel electrode (for example, the second pixel electrode CE of FIG. 4) to receive the electron from the second pixel electrode and transport the electron to the light emitting layer EML. In an example, the third functional layer IGL3 may be the electron transport layer ETL.

In an embodiment, the third functional layer IGL3 may include an outer surface (or upper surface) facing in an opposite direction of the inner surface (or lower surface) contacting the light emitting layer EML. The outer surface (or upper surface) may be opposite direction of the inner surface (or lower surface).

In an embodiment, the inner surface (or lower surface) of the third functional layer IGL3 may have a profile according to a shape of the outer surface (or upper surface) of the light emitting layer EML. In an example, the inner surface (or lower surface) of the third functional layer IGL3 may correspond to the third curved surface WS3 of the light emitting layer EML.

In an embodiment, the outer surface (or upper surface) of the third functional layer IGL3 may include an inclined surface inclined along the inclined surface of the light emitting layer EML and a flat surface FS connected to the inclined surface. The flat surface FS may be an area where a thickness of a stack structure of the first, second, and third functional layers IGL1, IGL2, and IGL3 and the light emitting layer EML is maintained constant.

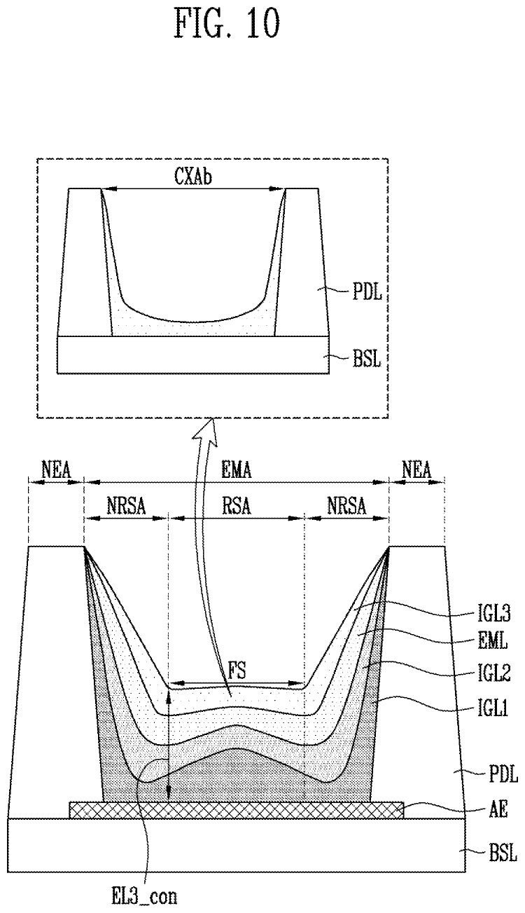

In an embodiment, the stack thickness of the first, second, and third functional layers IGL1, IGL2, and IGL3 and the light emitting layer EML may be maintained constant on the flat surface FS. The third functional layer IGL3, which allows the stack thickness of the first and second functional layers IGL1 and IGL2 and the light emitting layer EML to be maintained constant, may be disposed. A disposition and a design process of the third functional layer IGL3 are described later with reference to FIG. 10. The resonance satisfactory area RSA may be the emission area EMA corresponding to the flat surface FS, and may be an area in which the hole and the electron are balanced. The resonance unsatisfactory area NRSA may be an area excluding the resonance satisfactory area RSA from the emission area EMA, and may be an area in which light is not normally emitted due to constructive interference of the light emitted from the light emitting layer EML.

Referring to FIG. 6B, the resonance satisfactory area RSA may occupy most of the emission area EMA.

The display device according to embodiments may ensure an area (e.g., flat surface FS) in which the stack thickness of the first, second, and third functional layers IGL1, IGL2, and IGL3 and the light emitting layer EML is maintained constant according to individual shapes of each of the first, second, and third functional layers IGL1, IGL2, and IGL3 and the light emitting layer EML may be ensured.

Hereinafter, the disposition (or a shape) of the first, second, and third functional layers IGL1, IGL2, and IGL3 and the light emitting layer EML and a method of manufacturing them are described with reference to FIGS. 7, 8, 9, and 10.

FIG. 7 is a schematic cross-sectional view illustrating the disposition of the first functional layer and a method of forming the first functional layer according to an embodiment. FIG. 8 is a schematic cross-sectional view illustrating the disposition of the second functional layer and a method of forming the second functional layer according to an embodiment. FIG. 9 is a schematic cross-sectional view illustrating a disposition of the light emitting layer and a method of forming the light emitting layer according to an embodiment. FIG. 10 is a schematic cross-sectional view illustrating a disposition of the third functional layer and a method of forming the third functional layer according to an embodiment.

Referring to FIGS. 7, 8, 9, and 10, a method of manufacturing the display device according to embodiments may include forming the first pixel electrode AE on the base substrate BSL and forming the pixel defining layer PDL including an opening exposing the first pixel electrode AE on the first pixel electrode AE, forming the first functional layer IGL1 having the outer surface (or upper surface) on which the first concave portions CDA1 and the first convex portion CXA1 formed between the first concave portions CDA1 are formed, by applying a first organic material on the first pixel electrode AE and drying the first organic material (refer to FIG. 7), forming the light emitting layer EML on the first functional layer IGL1 (refer to FIG. 8), forming the third functional layer IGL3 having the outer surface (or upper surface) on which the flat surface FS overlapping the first convex portion CXA1 is formed by applying a third organic material on the light emitting layer EML and drying the third organic material (refer to FIG. 10), and forming the second pixel electrode (for example, the second pixel electrode CE of FIG. 4) on the third functional layer IGL3. The method of manufacturing the display device may further include forming the second functional layer IGL2 having the outer surface (or upper surface) on which the second concave portions CDA2 and the second convex portion CXA2 formed between the second concave portions CDA2 are formed (refer to FIG. 9).

Referring to FIG. 7, the first pixel electrode AE may be disposed and/or formed on the base substrate BSL. The pixel defining layer PDL including the opening exposing the first pixel electrode AE may be disposed and/or formed on the first pixel electrode AE. The first functional layer IGL1 may be disposed and/or formed on the first pixel electrode AE.

In an embodiment, the first functional layer IGL1 may be formed by applying on the first pixel electrode AE and drying (or curing) the first organic material.

In an embodiment, the first organic material may include a phthalocyanine compound such as copper phthalocyanine; DNTPD (N,N′-diphenyl-N,N′-bis-[4-(phenyl-m-tolyl-amino)-phenyl]-biphenyl4,4′-diamine), m-MTDATA (4,4′,4″-tris(3-methylphenylphenylamino) triphenylamine), TDATA (4,4′4″-Tris(N,N-diphenylamino)triphenylamine), 2TNATA (4,4′,4″-tris {N,-(2-naphthyl)-N-phenylamino}-triphenylamine), PEDOT/PSS(Poly(3,4-ethylenedioxythiophene)/Poly(4-styrenesulfonate), PANI/DBSA

(Polyaniline/Dodecylbenzenesulfonic acid), PANI/CSA (Polyaniline/Camphor sulfonicacid), PANI/PSS((Polyaniline)/Poly(4-styrenesulfonate), and the like, but embodiments are not limited thereto.

In an embodiment, the inner surface (or lower surface) of the first functional layer IGL1 may have the profile according to the shape of the pixel defining layer PDL and the first pixel electrode AE, but a surface shape of the outer surface (or upper surface) of the first functional layer IGL1 may be controlled according to a dry degree of the first organic material.

In an embodiment, the first organic material applied on the first pixel electrode AE may be dried by a vacuum dry device. For example, a surface shape of the first organic material may be controlled by varying the dry degree (e.g., a dry intensity, and/or a dry speed) for each position of the first organic material.

In an embodiment, the dry degree may be controlled according to heat, vapor pressure, and the like of an organic material. As the dry intensity increases (or the dry speed increases), a solvent may evaporate quickly, and thus a surface of the organic material may be formed to sink toward the base substrate BSL. As the dry intensity decreases (or the dry speed decreases), the surface of the organic material may be formed convex.

In an embodiment, the first concave portions CDA1 of the first functional layer IGL1 may be formed by drying an edge area of the first organic material at a first intensity. The edge area of the first organic material may be an area adjacent to the pixel defining layer PDL. In an example, the first convex portion CXA1 of the first functional layer IGL1 may be formed by drying a central area of the first organic material at a second intensity less than the first intensity. The central area of the first organic material may be an area surrounded by the edge area of the first organic material. The first convex portion CXA1 may be formed in the central area of the emission area EMA, and may be disposed and/or formed between the first concave portions CDA1.

In an embodiment, a dry speed of the edge area of the first organic material may be relatively fast, and thus the first concave portions CDA1 may be formed. A dry speed of the central area of the first organic material may be relatively slow, and thus the first convex portion CXA1 may be formed.

In an embodiment, the outer surface (or upper surface) of the first functional layer IGL1 may include a first inflection point P1. In an example, the first inflection point P1 may include a (1-1)-th inflection point and a (1-2)-th inflection point. The outer surface (or upper surface) of the first functional layer IGL1 may successively change from the first concave portion CDA1 to the first convex portion CXA1 based on the (1-1)-th inflection point of the first inflection point P1, and may successively change from the first convex portion CXA1 to the first concave portion CDA1 based on the (1-2)-th inflection point. In an example, the outer surface (or upper surface) of the first functional layer IGL1 may have the first curved surface (for example, the first curved surface WS1 of FIG. 6A) that changes from a concave shape to a convex shape based on the first inflection point P1 and successively changes from a convex shape to a concave shape.

In an embodiment, the lowest height IGL1_min of the first concave portions CDA1 and the highest height IGL1_max of the first convex portion CXA1 may be about 10 nm or more. In an example, the lowest height IGL1_min of the first concave portions CDA1 may be a height of the lowest point of the first concave portion CDA1 based on a surface of the first pixel electrode AE (or the base substrate BSL). The highest height IGL1_max of the first convex portion CXA1 may be a height of the highest point of the first convex portion CXA1 based on a surface of the first pixel electrode AE (or the base substrate BSL).

Referring to FIG. 8, the second functional layer IGL2 may be disposed and/or formed on the first functional layer IGL1.

In an embodiment, the second functional layer IGL2 may be formed by applying a second organic material on the first functional layer IGL1 and drying the second organic material.

In an embodiment, the second organic material may include a carbazole-based derivative such as N-phenylcarbazole or polyvinylcarbazole, a fluorene derivative, triphenylamine derivative such as TPD (N,N′-bis(3-methylphenyl)-N,N′-diphenyl-[1,1-biphenyl]-4,4′-diamine) and TCTA (4,4′,4″-tris(N-carbazolyl) triphenylamine), NPB(N,N′-di(1-naphthyl)-N,N′-diphenylbenzidine), TAPC (4,4′-Cyclohexylidene bis[N,N-bis(4-methylphenyl)benzenamine]), and the like, but embodiments are not limited thereto.

In an embodiment, the inner surface (or lower surface) of the second functional layer IGL2 may have the profile according to the shape of the outer surface (or upper surface) of the first functional layer IGL1, but the surface shape of the outer surface (or upper surface) of the second functional layer IGL2 may be controlled according to a dry degree of the second organic material.

In an embodiment, the second organic material applied on the first functional layer IGL1 may be dried by a vacuum dry device. For example, a surface shape of the second organic material may be controlled by varying the dry degree (a dry intensity, and/or a dry speed) for each position of the second organic material.

In an embodiment, the second concave portions CDA2 of the second functional layer IGL2 may be formed by drying an edge area of the second organic material at a fifth intensity. The edge area of the second organic material may be an area adjacent to the pixel defining layer PDL.

In an embodiment, the second convex portion CXA2 of the second functional layer IGL2 may be formed by drying a central area of the second organic material at a sixth intensity less than the fifth intensity. The central area of the second organic material may be an area surrounded by the edge area of the second organic material. The second convex portion CXA2 may be formed in the central area of the emission area EMA, and may be disposed and/or formed between the second concave portions CDA2.

In an embodiment, the second concave portions CDA2 may be formed by drying the edge area of the second organic material relatively quickly, and the second convex portion CXA2 may be formed by drying the central area of the second organic material relatively slowly.

In an embodiment, the fifth intensity may be less than the first intensity (e.g., dry intensity for forming the first concave portions CDA1 of the first functional layer IGL1). The sixth intensity may be greater than the second intensity (e.g., dry intensity for forming the first convex portion CXA1 of the first functional layer IGL1).

In an embodiment, a difference between the dry intensity for forming the first concave portions CDA1 and the dry intensity for forming the first convex portion CXA1 may be greater than a difference between the dry intensity for forming the second concave portion CDA2 and the dry intensity for forming the second convex portion CXA2.

In an embodiment, the outer surface (or upper surface) of the second functional layer IGL2 may include a second inflection point P2. The second inflection point P2 may include a (2-1)-th inflection point and a (2-2)-th inflection point. The outer surface (or upper surface) of the second functional layer IGL2 may successively change from the second concave portion CDA2 to the second convex portion CXA2 based on the (2-1)-th inflection point of the second inflection point P2, and successively change from the second convex portion CXA2 to the second concave portion CDA2 based on the (2-2)-th inflection point of the second inflection point P2. In an example, the outer surface (or upper surface) of the second functional layer IGL2 may have the second curved surface (for example, the second curved surface WS2 of FIG. 6A) that changes from a concave shape to a convex shape and successively changes from a convex shape to a concave shape based on the second inflection point P2.

In an embodiment, a difference between the lowest height EL1_min of a first stack structure and the highest height EL1_max of the first stack structure may be equal to or less than about 10 nm. In an example, the lowest height EL1_min of the first stack structure may be a height of the lowest point of the second concave portion CDA2 formed by disposing the second functional layer IGL2 on the first functional layer IGL1. The highest height EL1_max of the first stack structure may be a height of the highest point of the second convex portion CXA2 formed by disposing the second functional layer IGL2 on the first functional layer IGL1.

In another example, in case that the second organic material is applied on the base substrate BSL, which is on a flat surface, and the edge area of the second organic material is dried at the fifth intensity, a concave portion may be formed in an area corresponding to the second concave portions CDA2, and a height of the concave portion may be the lowest height IGL2_min of the second functional layer IGL2. In case that the second organic material is applied on the base substrate BSL, which is on a flat surface, and the central area of the second organic material is dried at the sixth intensity less than the fifth intensity, a convex portion may be formed in an area corresponding to the second convex portion CXA2, and a height of the convex portion may be the highest height IGL2_max of the second functional layer IGL2. In an example, the lowest height IGL2_min of the second functional layer IGL2 may be a distance at which the concave portion is spaced in the third direction DR3 from a surface of the first pixel electrode AE (or the base substrate BSL) in case that the second functional layer IGL2 is formed on the base substrate BSL, which is on a flat surface. The highest height IGL2_max of the second functional layer IGL2 may be a distance at which the convex portion is spaced apart from the convex portion in the third direction DR3 based on a surface of the first pixel electrode AE (or the base substrate BSL) in case that the second functional layer IGL2 is formed on the base substrate BSL, which is on a flat surface.

Referring to FIGS. 7 and 8, a difference between the highest height IGL1_max of the first functional layer IGL1 and the lowest height IGL1_min of the first functional layer IGL1 may be greater than a difference between the highest height IGL2_max of the second functional layer IGL2 and the minimum height IGL2_min of the second functional layer IGL2. However, embodiments are not limited thereto, and the difference between the highest height IGL1_max of the first functional layer IGL1 and the lowest height IGL1_min of the first functional layer IGL1 may be less than the difference between the highest height IGL2_max of the second functional layer IGL2 and the minimum height IGL2_min of the second functional layer IGL2.

Referring to FIG. 9, the light emitting layer EML may be disposed and/or formed on the second functional layer IGL2.

In an embodiment, the light emitting layer EML may be formed by applying a light emitting material on the second functional layer IGL2 and by drying the light emitting material.

In an embodiment, the light emitting material may include a low molecular or high molecular organic material. The low molecular organic material may include copper phthalocyanine (CuPc), N,N-di(naphthalene-1-yl)-N,N′-diphenyl-benzidine (N,N′-Di(naphthalene-1-yl)-N,N′-diphenyl-benzidine (NPB), tris-8-hydroxyquinoline aluminum (Alq3), and the like. The high molecular organic material may be formed by a method of inkjet printing or spin coating by using poly-(2,4)-ethylene-dihydroxy thiophene (PEDOT) or polyaniline (PANI), and a high molecular organic light emitting layer may include PPV, Soluble PPV's, CyanoPPV, Polyfluorene, and the like.

In an embodiment, the inner surface (or lower surface) of the light emitting layer EML may have the profile according to the shape of the outer surface (or upper surface) of the second functional layer IGL2, but the surface shape of the outer surface (or upper surface) of the light emitting layer EML may vary according to a dry degree of the light emitting material.

In an embodiment, the light emitting material applied on the second functional layer IGL2 may be dried by a vacuum dry device. For example, the surface shape of the light emitting material may be controlled by varying the dry degree (e.g., a dry intensity, and/or a dry speed) for each position of the light emitting material.

In an embodiment, the outer surface (or upper surface) of the light emitting layer EML may include a third inflection point P3. The third inflection point P3 may include a (3-1)-th inflection point and a (3-2)-th inflection point. The outer surface (or upper surface) of the light emitting layer EML may successively change from the third concave portion CDA3 to the third convex portion CXA3 based on the (3-1)-th inflection point of the third inflection point P3 and successively change from the third convex portion CXA3 to the third concave portion CDA3 based on the (3-2)-th inflection point of the third inflection point P3. In an example, the outer surface (or upper surface) of the light emitting layer EML may have the third curved surface (for example, the third curved surface WS3 of FIG. 6A) that changes from a concave shape to a convex shape and successively changes from a convex shape to a concave shape based on the third inflection point P3.

In an embodiment, a difference between the lowest height EL2_min of a second stack structure and the highest height EL2_max of the second stack structure may be less than the difference between the lowest height EL1_min of the first stack structure and the highest height EL1_max of the first stack structure. The lowest height EL2_min of the second stack structure may be the lowest height of a stack structure of the first and second functional layers IGL1 and IGL2 and the light emitting layer EML. For example, the lowest height EL2_min of the second stack structure may be a height of the lowest point of the third concave portion CDA3 formed by disposing the light emitting layer EML on the second functional layer IGL2. In an example, the highest height EL2_max of the second stack structure may be the highest height of the stack structure of the first and second functional layers IGL1 and IGL2 and the light emitting layer EML. For example, the highest height EL2_max of the second stack structure may be a height of the highest point of the third convex portion CXA3 formed by disposing the light emitting layer EML on the second functional layer IGL2.

In an embodiment, in case that the light emitting material is disposed on the second functional layer IGL2 and dried, the light emitting material may be formed in a surface shape for compensating for a degree of a curvature formed on the outer surface (or upper surface) of the second functional layer IGL2.

In another example, in case that the light emitting material is applied on the base substrate BSL, which is on a flat surface, and an edge area and a center area of the light emitting material are dried, a dry intensity of the center area of the light emitting material may be greater than that of the edge area of the light emitting material. For example, the outer surface (or upper surface) of the light emitting layer EML may be formed as a first concave surface CXAa. For example, in case that the light emitting layer EML is formed on the second functional layer IGL2, the outer surface (or upper surface) of the light emitting layer EML may be formed so that the third curved surface that changes from the concave shape to the convex shape and successively changes from the convex shape to the concave shape is formed.

Referring to FIG. 10, the third functional layer IGL3 may be disposed and/or formed on the light emitting layer EML.

In an embodiment, the third functional layer IGL3 may be formed by applying the third organic material on the light emitting layer EML and drying the third organic material.

In an embodiment, the third organic material may include Alq3 (Tris(8-hydroxyquinolinato)aluminum), TPBi (1,3,5-Tri (1-phenyl-1H-benzo[d]imidazol-2-yl)phenyl), BCP (2,9-Dimethyl-4,7-diphenyl-1,10-phenanthroline), Bphen (4,7-Diphenyl-1,10-phenanthroline), TAZ (3-(4-Biphenylyl)-4-phenyl-5-tert-butylphenyl-1,2,4-triazole), NTAZ (4-(Naphthalen-1-yl)-3,5-diphenyl-4H1,2,4-triazole), tBu-PBD (2-(4-Biphenylyl)-5-(4-tert-butylphenyl)-1,3,4-oxadiazole), BAlq (Bis(2-methyl8-quinolinolato-N1,O8)-(1,1′-Biphenyl-4-olato)aluminum), Bebq2 (berylliumbis(benzoquinolin-10-olate), ADN (9,10-di(naphthalene-2-yl) anthracene), and an alloy thereof, but embodiments are not limited thereto.

In an embodiment, the inner surface (or lower surface) of the third functional layer IGL3 may have a profile corresponding to a shape of the outer surface (or upper surface) of the light emitting layer EML, but a surface shape of the outer surface (or upper surface) of the third functional layer IGL3 may vary according to a dry degree of the third organic material.

In an embodiment, the third organic material applied on the light emitting layer EML may be dried by a vacuum dry device. For example, the surface shape of the third organic material may be controlled by varying the dry degree (e.g., a dry intensity, and/or a dry speed) for each position of the third organic material.

In an embodiment, the outer surface (or upper surface) of the third functional layer IGL3 may not include an inflection point. An edge area of the third organic material may be an inclined surface, and a central area of the third organic material may be the flat surface FS. The flat surface FS may be an area surrounded by the inclined surface. The flat surface FS may be an area in which a height EL3_con of a stack structure of the first, second, and third functional layers IGL1, IGL2, and IGL3 and the light emitting layer EML is maintained constant. In case that the third organic material is disposed on the light emitting layer EML and dried, the third organic material may be formed in a surface shape for compensating for the third curved surface (for example, the third curved surface WS3 of FIG. 6A) formed on the outer surface (or upper surface) of the light emitting layer EML.

In an embodiment, the inclined portion (or an area corresponding to the resonance unsatisfactory area NRSA) of the third functional layer IGL3 may be formed by drying the edge area of the third organic material at a third intensity.

In an embodiment, in the flat surface FS (or an area corresponding to the resonance satisfactory area RSA) of the third functional layer IGL3 may be formed by drying the central area of the third organic material at a fourth intensity greater than the third intensity.

In an embodiment, the flat surface FS of the third functional layer IGL3 may be formed by drying the central area of the third organic material relatively quickly, and an inclined portion of the third functional layer IGL3 may be formed by drying the edge area of the third organic material relatively slowly. In an example, the emission area EMA corresponding to the flat surface FS of the third functional layer IGL3 may be the resonance satisfactory area RSA. The emission area EMA corresponding to the inclined portion of the third functional layer IGL3 may be the resonance unsatisfactory area NRSA.

In an embodiment, the third intensity may be greater than the sixth intensity (e.g., dry intensity for forming the second convex portion CXA2 of the second functional layer IGL2).

In an embodiment, the fourth intensity may be less than the fifth intensity (e.g., dry intensity for forming the second concave portions CDA2 of the second functional layer IGL2).

In another example, the third organic material may be applied on the base substrate BSL, which is on a flat surface, the edge area of the third organic material may be dried at the third intensity, and the central area of the organic material may be dried at the fourth intensity greater than the intensity. For example, the outer surface (or upper surface) of the third functional layer IGL3 may be formed as a second concave surface CXAb.

The display device and the method of manufacturing the display device according to an embodiment may increase light emission efficiency by securing the resonance satisfactory area RSA through a combination of shapes of the outer surface (or upper surface) of each of the first, second, and third functional layers IGL1, IGL2, and IGL3 and the light emitting layer EML forming the organic light emitting unit of the light emitting element.

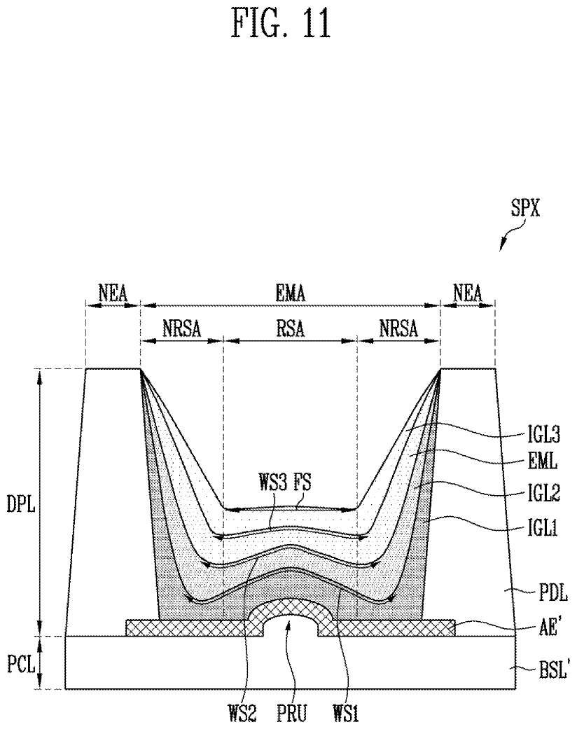

FIG. 11 is a schematic cross-sectional view illustrating another embodiment of the sub-pixel of FIG. 4.

Referring to FIG. 11, components other than a base substrate BSL′ and a first pixel electrode AE′ may be the same as or correspond to those shown in FIG. 6A.

Referring to FIG. 11, the base substrate BSL′ may include a protrusion portion PRU in an area overlapping the resonance satisfactory area RSA. In an example, the protrusion portion PRU may be formed by partially etching the base substrate BSL′. The protrusion portion PRU may be formed by removing a surface of the base substrate BSL′ corresponding to a remaining area except for the resonance satisfactory area RSA.

In an embodiment, the first pixel electrode AE′ may be disposed and/or formed on the base substrate BSL′ including the protrusion portion PRU. The first pixel electrode AE′ may include an inner surface (or lower surface) contacting the base substrate BSL′ and an outer surface (or upper surface) contacting the first functional layer IGL1. The inner surface (or lower surface) and the outer surface (or upper surface) of the first pixel electrode AE′ may have a surface profile corresponding to a shape of the protrusion portion PRU. Accordingly, the inner surface (or lower surface) of the first functional layer IGL1 disposed on the first pixel electrode AE′ may include a protruding surface according to a shape of the outer surface (or upper surface) of the first pixel electrode AE′.

The display device according to embodiments may ensure an area (e.g., flat surface FS) where a stack thickness of the first, second, and third functional layers IGL1, IGL2, and IGL3 and the light emitting layer EML is maintained constant according to individual shapes of each of the first, second, and third functional layers IGL1, IGL2, and IGL3 and the light emitting layer EML.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a base substrate;
a first pixel electrode disposed on the base substrate;
a pixel defining layer disposed on the first pixel electrode and including an opening exposing the first pixel electrode;
an organic light emitting unit disposed on the first pixel electrode; and
a second pixel electrode disposed on the organic light emitting unit, wherein
the organic light emitting unit comprises:
a first functional layer disposed on the first pixel electrode and including a lower surface contacting the first pixel electrode and an upper surface opposite to the lower surface;
a light emitting layer disposed on the first functional layer; and
a third functional layer disposed on the light emitting layer and including a lower surface contacting the light emitting layer and an upper surface opposite to the lower surface,
the upper surface of the first functional layer includes first concave portions and a first convex portion formed between the first concave portions, and
the upper surface of the third functional layer includes a flat surface overlapping the first convex portion of the first functional layer in a plan view.

2. The display device according to claim 1, wherein
the upper surface of the third functional layer includes inclined surfaces, and
the flat surface of the third functional layer is disposed between the inclined surfaces of the third functional layer.

3. The display device according to claim 1, further comprising:
a second functional layer disposed between the first functional layer and the light emitting layer and including a lower surface contacting the first functional layer and an upper surface contacting the organic light emitting unit,
wherein the upper surface of the second functional layer includes second concave portions and a second convex portion formed between the second concave portions.

4. The display device according to claim 3, wherein a difference between a minimum height of the second concave portions and a maximum height of the second convex portion is less than a difference between a minimum height of the first concave portions and a maximum height of the first convex portion.

5. The display device according to claim 3, wherein a difference between a height of a lowest point of the second concave portions and a height of a highest point of the second convex portion is equal to or less than about 10 nm.

6. The display device according to claim 3, wherein
the light emitting layer includes a lower surface contacting the upper surface of the second functional layer and an upper surface contacting the lower surface of the third functional layer,
the lower surface of the second functional layer has a surface profile of the upper surface of the first functional layer, and
the lower surface of the light emitting layer has a surface profile of the upper surface of the second functional layer.

7. The display device according to claim 3, wherein the second convex portion overlaps the first convex portion in a plan view.

8. The display device according to claim 3, wherein the upper surface of the first functional layer includes at least one first inflection point,
the upper surface of the second functional layer includes at least one second inflection point, and
the at least one first inflection point is closer to the pixel defining layer than the at least one second inflection point.

9. The display device according to claim 8, wherein
the at least one first inflection point includes a (1-1)-th inflection point and a (1-2)-th inflection point,
the at least one second inflection point includes a (2-1)-th inflection point and a (2-2)-th inflection point,
the first convex portion is formed between the (1-1)-th inflection point and the (1-2)-th inflection point, and
the second convex portion is formed between the (2-1)-th inflection point and the (2-2)-th inflection point.

10. The display device according to claim 3, wherein
the first functional layer includes a hole injection layer,
the second functional layer includes a hole transport layer, and
the third functional layer includes an electron transport layer.

11. The display device according to claim 1, wherein the upper surface of the third functional layer does not include an inflection point.

12. The display device according to claim 1, wherein
the lower surface of the first functional layer has a profile according to a surface shape of the first pixel electrode, and
the lower surface of the first functional layer has a flat profile.

13. The display device according to claim 1, wherein
the base substrate includes a protrusion portion overlapping the first convex portion in a plan view and protruding in a third direction, and
the first pixel electrode is disposed on the base substrate and has a surface profile according to a shape of the protrusion portion.

14. A method of manufacturing a display device, the method comprising:
forming a first pixel electrode on a base substrate;
forming a pixel defining layer including an opening exposing the first pixel electrode on the first pixel electrode;
forming a first functional layer having an upper surface formed with first concave portions and a first convex portion formed between the first concave portions by applying and drying a first organic material on the first pixel electrode;
forming a light emitting layer on the first functional layer;
forming a third functional layer having an upper surface formed with a flat surface overlapping the first convex portion by applying and drying a third organic material on the light emitting layer; and
forming a second pixel electrode on the third functional layer.

15. The method according to claim 14, wherein the drying of the first organic material comprises:
forming the first concave portions by drying an edge area of the first organic material at a first intensity; and
forming the first convex portion by drying a central area of the first organic material at a second intensity less than the first intensity.

16. The method according to claim 15, wherein the drying of the third organic material comprises:
forming inclined surfaces by drying an edge area of the third organic material at a third intensity between the first intensity and the second intensity; and
forming the flat surface by drying a central area of the third organic material at a fourth intensity greater than the third intensity and less than the first intensity.

17. The method according to claim 16, further comprising:
forming a second functional layer having an upper surface formed with second concave portions and a second convex portion formed between the second concave portions by applying and drying a second organic material on the first functional layer.

18. The method according to claim 17, wherein
the drying of the second organic material comprises:
forming the second concave portions by drying an edge area of the second organic material at a fifth intensity; and
forming the second convex portion by drying a central area of the second organic material at a sixth intensity,
the fifth intensity is less than the first intensity and greater than the fourth intensity, and
the sixth intensity is greater than the second intensity and less than the third intensity.

19. The method according to claim 18, wherein
the first functional layer includes a hole injection layer,
the second functional layer includes a hole transport layer, and
the third functional layer includes an electron transport layer.

20. The method according to claim 14, further comprising:
forming a protrusion portion in an area corresponding to the first convex portion by partially etching the base substrate,
wherein the first pixel electrode is formed on the protrusion portion.
